(19) United States
(12) Patent Application Publication
(10) Pub. No.: US 2025/0081294 A1
(43) Pub. Date: Mar. 6, 2025

(54) HEATING DEVICE

(71) Applicant: NITERRA CO., LTD., Nagoya-shi (JP)

(72) Inventor: Hiroki Hattori, Nagoya-shi (JP)

(73) Assignee: NITERRA CO., LTD., Nagoya-shi (JP)

(21) Appl. No.: 18/812,464

(22) Filed: Aug. 22, 2024

(30) Foreign Application Priority Data
Sep. 5, 2023 (JP) 2023-143417

(51) Int. Cl. H05B 3/24; H05K 7/20

(52) U.S. Cl. CPC H05B 3/24; H05K 7/20418

(57) ABSTRACT

A heating device 10 including: a circuit board 12; an electronic component 13 provided on the circuit board 12; a casing 20 having formed therein a storage space 29 in which the circuit board 12 is stored and a flow path 21 through which a heat medium flows; and a heater 11 which is provided in the flow path 21 and heats the heat medium, wherein a plurality of wall portions forming the storage space 29 include a contact wall portion 26 with which the electronic component 13 indirectly contacts, and the contact wall portion 26 contacts with outside air.

### BACKGROUND

### 1. Field of the Disclosure

The present disclosure relates to a heating device.

### 2. Description of Related Art

One conventional example of a heat medium heating device used for a vehicular air conditioner is described in Japanese Patent Application Laid-Open (kokai) No. 2018-133300 (Patent Document 1 below). The heat medium heating device includes a casing in which a heat medium flows, a positive temperature coefficient (PTC) heater which heats the heat medium, and a control board which controls the PTC heater. The casing includes a board storage portion which stores the control board. The control board has electronic components, including heat-generating electronic components such as an insulated gate bipolar transistor (IGBT) and a field effect transistor (FET), and electronic components other than these, may be used.

[Patent Document 1] Japanese Patent Application Laid-Open (kokai) No. 2018-133300.

### 3. Problem(s) to be Solved

In the above configuration, the electronic components are placed in an internal space of the board storage portion and do not contact with members other than a board body of the control board. Here, in a case where the electronic components include a heat-generating one, heat generated from the electronic component is transferred to air in the board storage portion. In this case, heat is not sufficiently released from the electronic component and thus is overheated, so that the electronic component might become unable to function normally.

### SUMMARY OF THE DISCLOSURE

The present disclosure was completed based on the above circumstances.

An object of the present disclosure, for example, is to provide a heating device in which the effect of heat dissipation of one or more heat-generating electronic components can be enhanced.

A heating device of the present disclosure may include, for example: a circuit board; an electronic component provided on the circuit board; a casing having formed therein a storage space in which the circuit board is stored and a flow path through which a heat medium flows; and a heater which is provided in the flow path and heats the heat medium, wherein a plurality of wall portions forming the storage space include a contact wall portion with which the electronic component directly or indirectly contacts, and the contact wall portion contacts with outside air.

According to the present disclosure, there can be obtained a heating device in which the effect of heat dissipation of a heat-generating electronic component can be enhanced.

Additional features and advantages of the present disclosure are described further below. This summary section is meant merely to illustrate certain features of the disclosure, and is not meant to limit the scope of the disclosure in any way. The failure to discuss a specific feature or embodiment of the disclosure, or the inclusion of one or more features in this summary section, should not be construed to limit the claims.

### BRIEF DESCRIPTION OF THE DRAWINGS

The figures contained herein are provided only by way of example and not by way of limitation.

FIG. 1 Exploded perspective view of a heating device according to embodiment 1.

FIG. 2 Perspective view of the heating device.

FIG. 3 Sectional view along line A-A in FIG. 2.

FIG. 4 Enlarged view of FIG. 3.

FIG. 5 Perspective view of an electronic component provided on a circuit board.

FIG. 6 Back view of the heating device showing arrangement of the electronic components at a contact wall portion.

FIG. 7 Sectional view of a heating device according to embodiment 2, which corresponds to FIG. 3 in embodiment 1.

### DESCRIPTION OF REFERENCE NUMERALS

Reference numerals used to identify various features in the drawings include the following:

10, 110 heating device

11 heater, 11A1 internal space, 11A cylindrical member, 11B flange portion

12 circuit board, 13 electronic component, 13A body portion, 13A1 back surface, 13B lead portion, 15, 16 lead wire, 17 wire

20, 120 casing, 21 flow path, 21A inlet, 21B outlet, 22 flow path member, 22A tube portion, 22B fixation member, 22B1 flange portion, 22B2 pressing portion, 22C bottom wall, 22D branch portion, 23, 123 board storage portion, 23A first wall portion, 23B second wall portion, 23C third wall portion, 23D fourth wall portion, 23E fifth wall portion, 24 thermometer, 25 terminal storage portion, 26, 126 contact wall portion, 27 box portion, 28 casing body, 29 storage space

40 insulating material, 41 through hole

50 heat conductor

CP central-side part

S1, S2, S3 seal member

126A fin

### DETAILED DESCRIPTION

It is to be understood that both the foregoing general description and the following detailed description are exemplary and are intended to provide further explanation of the claims. Accordingly, various changes, modifications, and equivalents of the methods, apparatuses, and/or systems described herein will be apparent to those of ordinary skill in the art. Moreover, descriptions of well-known functions and constructions may be omitted for increased clarity and conciseness.

The terms used in the description are intended to describe embodiments only, and shall by no means be restrictive. Unless clearly used otherwise, expressions in a singular form include a meaning of a plural form. In the present description, an expression such as “comprising” or “including” is intended to designate a characteristic, a number, a step, an operation, an element, a part or combinations thereof, and shall not be construed to preclude any presence or possibility of one or more other characteristics, numbers, steps, operations, elements, parts or combinations thereof.

If used herein, “about,” “approximately,” “substantially,” and “significantly” will be understood by a person of ordinary skill in the art and will vary in some extent depending on the context in which they are used. If there are uses of the term which are not clear to persons of ordinary skill in the art given the context in which it is used, “about” and “approximately” will mean plus or minus ≤10% of particular term, and “substantially” and “significantly” will mean plus or minus >10% of the particular term.

First, example embodiments of the present disclosure will be listed and described.

[1] A heating device of the present disclosure is a heating device including, for example: a circuit board; an electronic component provided on the circuit board; a casing having formed therein a storage space in which the circuit board is stored and a flow path through which a heat medium flows; and a heater which is provided in the flow path and heats the heat medium, wherein a plurality of wall portions forming the storage space include a contact wall portion with which the electronic component directly or indirectly contacts, and the contact wall portion contacts with outside air.

With this configuration, heat of the electronic component can be transferred to outside air via the contact wall portion.

[2] In the above [1], the contact wall portion may have, for example, a largest outside-air contact area among the plurality of wall portions.

With this configuration, since the contact wall portion has the largest outside-air contact area among the plurality of wall portions, the effect of heat dissipation from the electronic component to outside air can be further enhanced.

[3] In the above [1] or [2], the casing may be formed, for example, by having the contact wall portion and a casing body to/from which the contact wall portion is attachable/detachable.

With this configuration, it becomes easy to store the circuit board in the storage space in a state in which the electronic component contacts with the contact wall portion.

[4] In the above any one of [1] to [3], the contact wall portion may have, for example, a plurality of fins contacting with the outside air.

With this configuration, the area of the contact wall portion that contacts with outside air is increased by the plurality of fins, whereby the effect of heat dissipation from the electronic component to outside air can be further enhanced.

[5] In the above any one of [1] to [4], the contact wall portion may be formed, for example, of a heat dissipation plate made of metal or metal alloy.

With this configuration, heat dissipation performance of the contact wall portion can be increased, whereby the effect of heat dissipation from the electronic component to outside air can be further enhanced.

[6] In the above any one of [1] to [5], the electronic component may, for example, be in contact with a central-side part of the contact wall portion.

With this configuration, as compared to a case where the electronic component is in contact with an outer peripheral part of the contact wall portion, heat of the electronic component is more likely to be equally transferred to the entire contact wall portion, whereby the effect of heat dissipation from the electronic component to outside air can be further enhanced. [Details of embodiment 1 of present disclosure]

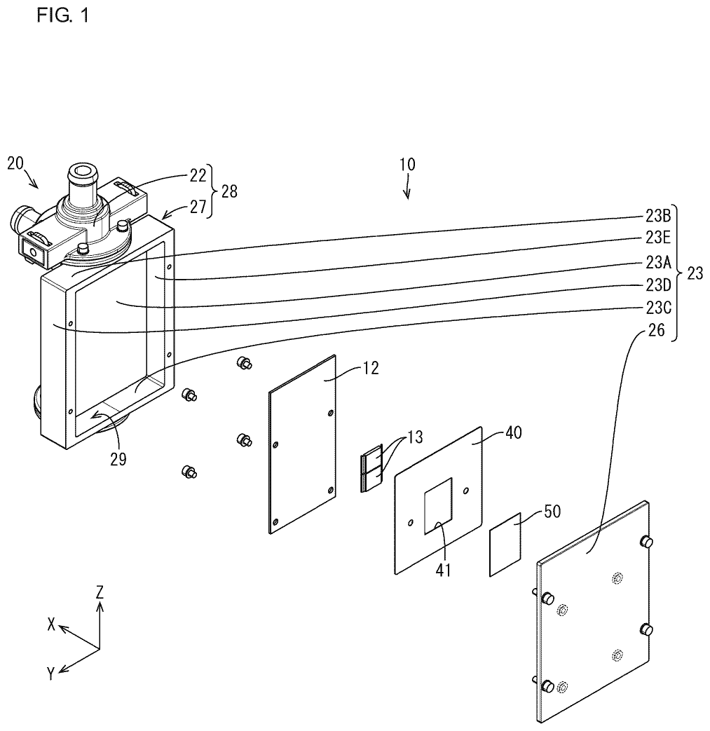

Embodiment 1 of the present disclosure will be described with reference to FIG. 1 to FIG. 6.

In the following description, for a plurality of identical members, only some of these members may be denoted by reference characters and reference characters of the other members may be omitted. Here, a Z-axis positive direction is defined as an upward direction, a Z-axis negative direction is defined as a downward direction, an X-axis positive direction is defined as a frontward direction, and a Y-axis positive direction is defined as a leftward direction, to describe the configuration of a heating device 10. However, in an actual usage condition of the heating device 10, different arrangement may be applied.

### Heating Device

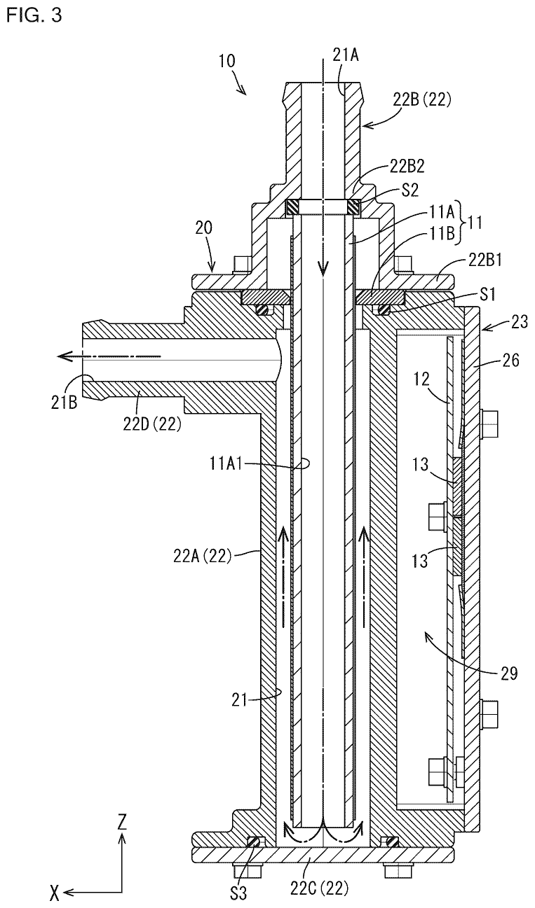

The heating device 10 according to the present embodiment is a device for heating a liquid such as water (example of heat medium). For example, the heating device 10 is provided to an electric vehicle (EV) and may be used, for example, for heating a vehicle compartment or retaining heat of a battery. As shown in FIG. 3, the heating device 10 includes a heater 11, a circuit board 12, and a casing 20 storing the heater 11 and the circuit board 12.

### Heater

The heater 11 of the present embodiment may be a ceramic heater. The heater 11 includes a cylindrical member 11A and a heating resistor (not shown) buried inside the cylindrical member 11A. The cylindrical member 11A may, for example, be mainly formed (e.g., 50% by mass or more of a total mass of the cylindrical member) of a ceramic material such as alumina. The heating resistor may be made of metal, such as tungsten, and has a thin-wire meandering shape. The heating resistor generates heat by voltage being applied thereto from a power supply device (not shown). The heater 11 can be manufactured, for example, by interposing a metal pattern to be a heating resistor between ceramic green sheets, wrapping them around a rod-shaped form member, and then performing firing. The heater 11 includes a flange portion 11B brazed to an outer circumferential surface of the cylindrical member 11A. The flange portion 11B has a plate shape and forms a circular ring shape. The flange portion 11B is provided at an upper-end-side position of the cylindrical member 11A.

### Circuit Board and Electronic Component

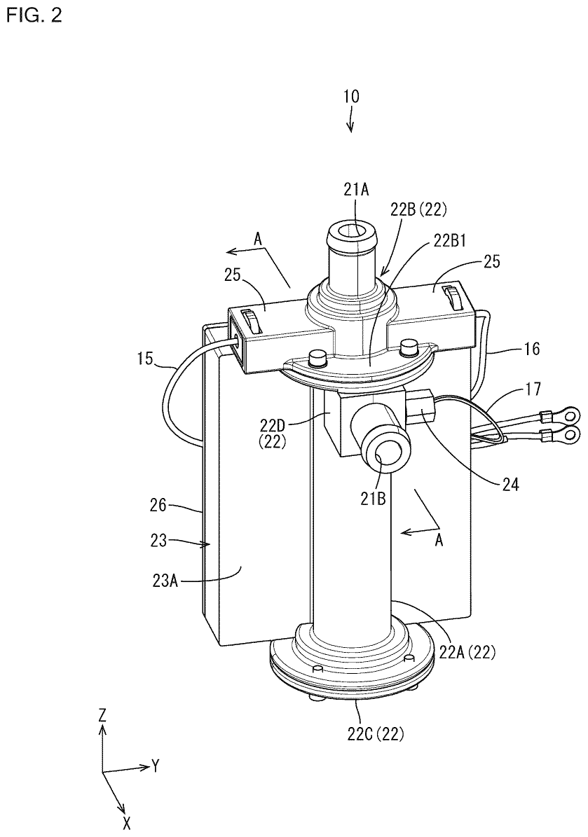

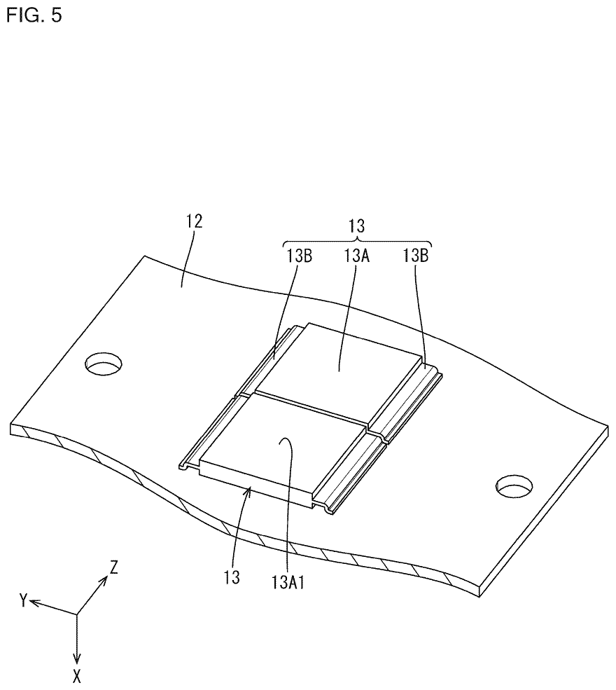

As shown in FIG. 5, electronic components 13 for controlling an output of the heater 11 are provided at one surface (back surface) of the circuit board 12. The electronic components 13 are switching elements such as FET or IGBT, for example. The electronic components 13 have a characteristic that heat is readily generated, the heat generation amount thereof is smaller than that of the heater 11, and the electronic components 13 generate heat when being energized. Each electronic component 13 includes a body portion 13A and lead portions 13B electrically connected to the circuit board 12. The body portion 13A is made of resin and has a semiconductor element or the like buried therein. The lead portions 13B are provided at side surfaces of the body portion 13A. The lead portion 13B may be provided at a bottom surface of the body portion 13A (a surface opposed to the circuit board 12; a front surface). Although not shown in detail, lead wires 15, 16 (see FIG. 2) connected to the heater 11 and a wire 17 (see FIG. 2) connected to each measurement device such as a thermometer 24 are electrically connected to the circuit board 12.

### Casing

As shown in FIG. 3, the casing 20 includes a flow path member 22 forming a flow path 21 through which a liquid flows, and a board storage portion 23 in which the circuit board 12 is stored. The flow path member 22 may be made of resin. The heater 11 is placed in the flow path 21.

As shown in FIG. 2, the flow path member 22 includes a tube portion 22A having a substantially cylindrical shape, a fixation member 22B attached to an upper end of the tube portion 22A, a bottom wall 22C closing a lower end of the tube portion 22A, and a tubular branch portion 22D branching from the tube portion 22A. The fixation member 22B has a substantially tubular shape. The fixation member 22B has an inlet 21A at one end of the flow path 21. The fixation member 22B has a flange portion 22B1 at a lower end. The flange portion 22B1 may be fixed to the tube portion 22A by being fastened with bolts, so as to close an opening at the upper end of the tube portion 22A. As shown in FIG. 3, the flange portion 22B1 presses the flange portion 11B of the heater 11 downward. Thus, a seal member S1 provided between the flange portion 11B of the heater 11 and an opening edge of the tube portion 22A is compressed, and the flange portion 11B and the tube portion 22A are sealed in a liquid-tight state. A pressing portion 22B2 having a stepped shape with its diameter expanded outward is provided at an up-down-direction center part of the fixation member 22B. The pressing portion 22B2 presses an upper end of the cylindrical member 11A of the heater 11 via a seal member S2. Thus, the inlet 21A and the internal space 11A1 of the cylindrical member 11A communicate with each other and the fixation member 22B and the cylindrical member 11A are sealed in a liquid-tight state.

The bottom wall 22C closes an opening at a lower end of the tube portion 22A with a seal member S3 therebetween. The branch portion 22D is formed integrally with the tube portion 22A. The branch portion 22D protrudes frontward from an upper-end-side part of the tube portion 22A. The branch portion 22D has an outlet 21B at another end of the flow path 21. As shown in FIG. 2, a thermometer 24 for measuring the temperature of a liquid flowing near the outlet 21B can be provided at the branch portion 22D.

As shown by arrows (unlabeled) in FIG. 3, the liquid is introduced from the inlet 21A and passes downward through the internal space 11A1 of the heater 11. Thereafter, the liquid is discharged to the outside of the heater 11 from an opening at a lower end of the cylindrical member 11A, and moves upward through the flow path 21 on the outer side of the heater 11. Then, the liquid is discharged to the outside through the outlet 21B at an upper-end-side position of the tube portion 22A.

As shown in FIG. 2, the fixation member 22B is provided with box-shaped terminal storage portions 25 on both lateral sides thereof. Terminals (not shown) are stored in the terminal storage portions 25. Although the detailed description is omitted, positive and negative electrodes of the heater 11 are electrically connected to the lead wires 15, 16 via the terminals.

The board storage portion 23 may, for example, be formed of six wall portions and have a rectangular parallelepiped shape. For example, as shown in FIG. 1, the board storage portion 23 has a first wall portion 23A, a second wall portion 23B extending backward from an upper end of the first wall portion 23A, a third wall portion 23C extending backward from a lower end of the first wall portion 23A, a fourth wall portion 23D extending backward from a left end of the first wall portion 23A, a fifth wall portion 23E extending backward from a right end of the first wall portion 23A, and a contact wall portion 26 located in opposition to the first wall portion 23A in the front-back direction. The second to fifth wall portions 23B to 23E form a quadrangular tube shape. As shown in FIG. 2, the first wall portion 23A extends in the left-right direction from a back end of the tube portion 22A.

### Contact Wall Portion

As shown in FIG. 1, the first to fifth wall portions 23A to 23E form a box portion 27 which opens backward. The box portion 27 may be made of resin and is formed integrally with the flow path member 22. In other words, the box portion 27 and the flow path member 22 form a casing body 28. The contact wall portion 26 is formed of a heat dissipation plate and may be made of metal or metal alloy. For example, the contact wall portion 26 may be made of aluminum. The contact wall portion 26 is attachable/detachable to/from the box portion 27 (casing body 28). For example, the contact wall portion 26 may be fixed to the box portion 27 by being fastened with bolts. The box portion 27 and the contact wall portion 26 form a storage space 29 in which the circuit board 12 is stored. At the contact wall portion 26, an insulating material 40 and a heat conductor 50 having an insulating property are stacked from the front side. The second to fifth wall portions 23B to 23E and the contact wall portion 26 form a part of the outer surface of the heating device 10 and contact with outside air.

The insulating material 40 may have a plate shape. The insulating material 40 may be formed, for example, of a polyethylene (PE), polypropylene (PP), polyvinyl chloride (PVC), polystyrene (PS), polyamide (e.g., PA6/Nylon 6), perfluoroalkoxy (PFA), polytetrafluoroethylene (PTFE), fluorine-based resin, or the like, for example. The insulating material 40 is shown having a rectangular through hole 41 substantially at a center part. The insulating material 40 may be fixed to the contact wall portion 26 by, for example, being fastened with bolts.

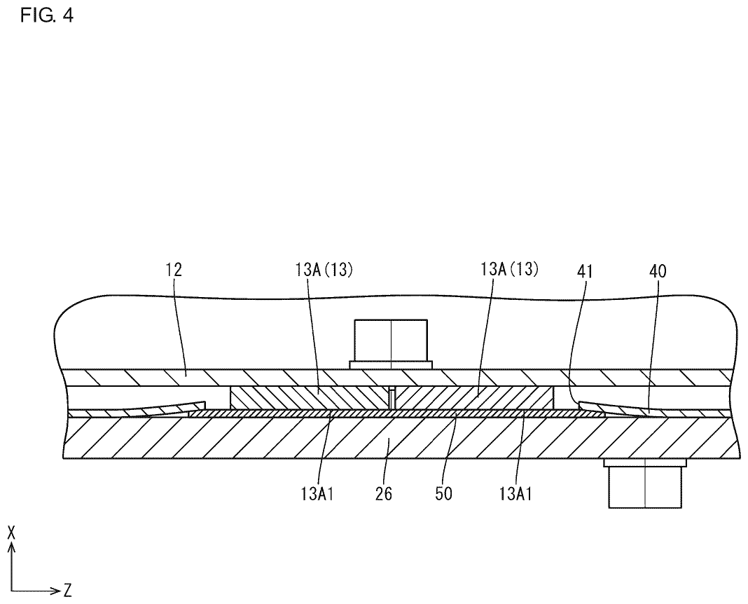

The heat conductor 50 has a sheet shape and is formed of resin or the like, for example. The thermal conductivity of the heat conductor 50 may be, for example, not less than 1.0×10−4 cal/cm.sec.° C. The heat conductor 50 is preferably elastic and capable of being deformed while being able to recover its shape to a certain extent. That is, deformation of the heat conductor 50 is different from plastic deformation. The heat conductor 50 is fixed while being interposed between the contact wall portion 26 and the insulating material 40. The heat conductor 50 has a rectangular shape slightly larger than the through hole 41 of the insulating material 40. As shown in FIG. 4, an outer edge of the heat conductor 50 is held between a hole edge of the through hole 41 and the contact wall portion 26. Thus, the heat conductor 50 is exposed to the circuit board 12 side via the through hole 41.

As shown in FIG. 3, the circuit board 12 is located toward the contact wall portion 26 side in the storage space 29. The circuit board 12 may be fixed to the contact wall portion 26 by being fastened with bolts. As shown in FIG. 4, each electronic component 13 is placed in contact with the heat conductor 50. Specifically, of the electronic component 13, a back surface 13A1 of the body portion 13A is pressed in contact with a front surface of the heat conductor 50 exposed to the circuit board 12 side via the through hole 41 of the insulating material 40. Thus, heat generated from the electronic components 13 through control of the heater 11 can be transferred to outside air through the heat conductor 50 and the contact wall portion 26. Therefore, the electronic components 13 can be cooled. In addition, since the heat conductor 50 has an insulating property, electric discharge between the electronic components 13 and the contact wall portion 26 is suppressed.

When the heat conductor 50 is elastic, damage to the electronic components 13 can be suppressed even though the electronic components 13 are pressed against the heat conductor 50. Further, when the electronic components 13 are pressed against the heat conductor 50, adhesion between the heat conductor 50 and the electronic components 13 can be enhanced, whereby the effect of heat dissipation from the electronic components 13 to the contact wall portion 26 can be enhanced.

The heating device 10 according to the present embodiment is particularly suitable for use in a cold area where the outside air temperature is low (e.g., not higher than 0° C.). In a case where the heating device 10 is used in a cold area, the electronic components 13 can be cooled more efficiently.

As shown in FIG. 1, the contact wall portion 26 has a largest outside-air contact area among the six wall portions. Therefore, heat of the electronic components 13 can be released to outside air more efficiently as compared to a case where the contact wall portion is located at another wall portion unlike the present embodiment.

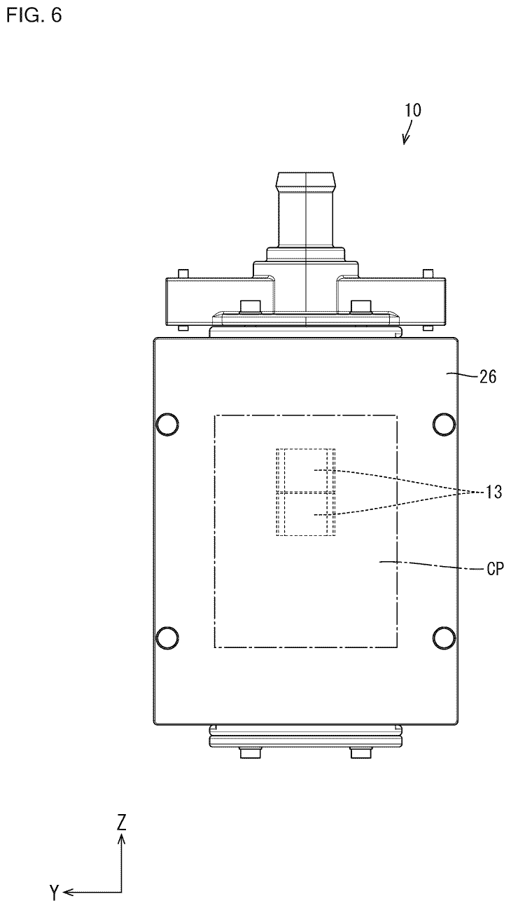

As shown in FIG. 6, in the present embodiment, the electronic components 13 are in contact with a central-side part CP of the contact wall portion 26. Here, where the distance from the center of the contact wall portion 26 to an outer edge thereof is denoted by D, the central-side part CP may be an area within a distance of 0.6 D from the center, for example. Since the electronic components 13 are in contact with the central-side part CP of the contact wall portion 26, heat of the electronic components 13 is more likely to be equally transferred to the entire contact wall portion 26, as compared to a case where the electronic components 13 contact with an outer peripheral part (a part other than the central-side part CP) of the contact wall portion 26. As a result, the effect of heat dissipation from the electronic components 13 to outside air can be further enhanced.

### Effects of Embodiment 1

(1-1) The heating device 10 of embodiment 1 is a heating device 10 including, for example: a circuit board 12; an electronic component 13 provided on the circuit board 12; a casing 20 having formed therein a storage space 29 in which the circuit board 12 is stored and a flow path 21 through which a heat medium flows; and a heater 11 which is provided in the flow path 21 and heats the heat medium, wherein a plurality of wall portions forming the storage space 29 include a contact wall portion 26 with which the electronic component 13 indirectly contacts, and the contact wall portion 26 contacts with outside air.

With this configuration, heat of the electronic component 13 can be transferred to outside air via the contact wall portion 26.

(1-2) In embodiment 1, the contact wall portion 26 may have the largest outside-air contact area among a plurality of wall portions.

With this configuration, since the contact wall portion 26 has a largest outside-air contact area among the plurality of wall portions, the effect of heat dissipation from the electronic component 13 to outside air can be further enhanced.

(1-3) In embodiment 1, the casing 20 can be formed by having the contact wall portion 26 and a casing body 28 to/from which the contact wall portion 26 being configured to be easily attachable/detachable.

With this configuration, it becomes easy to store the circuit board 12 in the storage space 29 in a state in which the electronic component 13 contacts with the contact wall portion 26.

(1-4) In embodiment 1, the contact wall portion 26 can be formed of a heat dissipation plate made of metal.

With this configuration, heat dissipation performance of the contact wall portion 26 can be increased, whereby the effect of heat dissipation from the electronic component 13 to outside air can be further enhanced.

(1-5) In embodiment 1, the electronic component 13 may be in contact with a central-side part CP of the contact wall portion 26.

With this configuration, as compared to a case where the electronic component 13 contacts with an outer peripheral part of the contact wall portion 26, heat of the electronic component 13 is more likely to be equally transferred to the entire contact wall portion 26, whereby the effect of heat dissipation from the electronic component 13 to outside air can be further enhanced.

### Details of Embodiment 2 of Present Disclosure

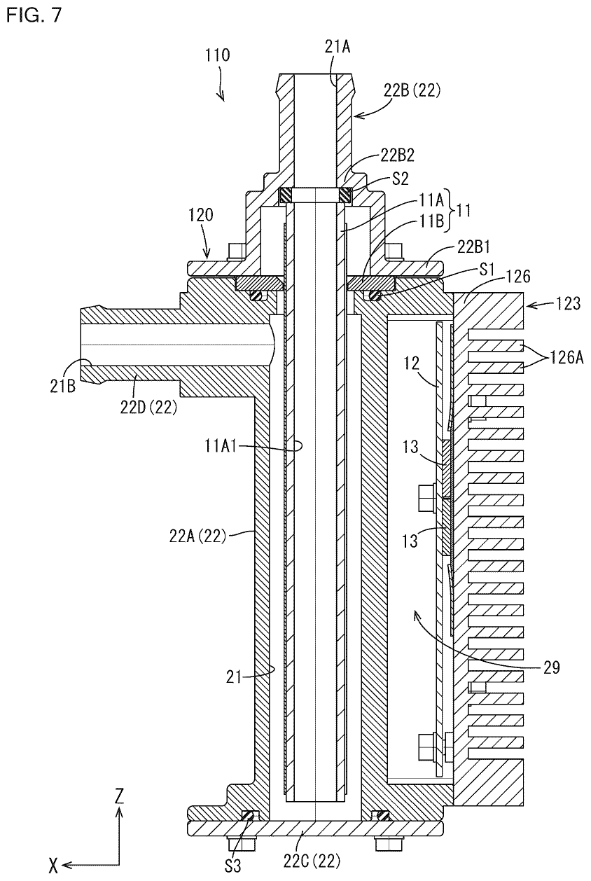

Embodiment 2 of the present disclosure will be described with reference to FIG. 7. A heating device 110 of embodiment 2 has the same configuration as the heating device 10 of embodiment 1 except for a configuration of a contact wall portion 126. Hereinafter, the same members as those in embodiment 1 are denoted by the same reference characters and the description thereof is omitted.

A casing 120 of embodiment 2 includes the flow path member 22 and a board storage portion 123. The board storage portion 123 has the same configuration as in embodiment 1 except for the contact wall portion 126. The contact wall portion 126 has a plurality of fins 126A on an outer surface contacting with outside air. The fins 126A may have thin plate shapes and protrude from the outer surface of the contact wall portion 126. Each fin 126A extends in the left-right direction and is flattened in the up-down direction. The plurality of fins 126A are arranged in the up-down direction. Owing to the fins 126A provided on the contact wall portion 126, the surface area where the contact wall portion 126 contacts with outside air can be increased. Thus, the effect of heat dissipation from the contact wall portion 126 to outside air can be enhanced. Therefore, the electronic components 13 can be efficiently cooled. The fins 126A may be provided over an entirety of the contact wall portion 126 that contacts with the outside air, as shown in FIG. 7, or may be provided only on a portion of the contact wall portion.

### Effects of Embodiment 2

(2-1) In the heating device 110 of embodiment 2, the contact wall portion 126 has a plurality of fins 126A contacting with the outside air.

With this configuration, the area of the contact wall portion 126 that contacts with outside air is increased by the plurality of fins 126A, whereby the effect of heat dissipation from the electronic component 13 to outside air can be further enhanced.

### Other Embodiments

(1) In the above embodiments 1 and 2, the heater 11 is described as being a ceramic heater. However, the heater may be a PTC heater or a sheath heater.

(2) In the above embodiments 1 and 2, the heater 11 is described as having a cylindrical shape. However, the shape of the heater may be changed as appropriate.

(3) In the above embodiments 1 and 2, the heat conductor 50 is described as being elastic. However, for example, the heat conductor may be plastically deformable without being elastic.

(4) In the above embodiments 1 and 2, the contact wall portion 26, 126 is described of being made of metal or metal alloy. However, the contact wall portion may not necessarily be made of metal. The contact wall portion may be made of ceramic or resin, for example.

(5) In the above embodiments 1 and 2, the electronic components 13 are described as indirectly being in contact with the contact wall portion 26, 126 via the heat conductor 50. However, for example, in a case where the contact wall portion has an insulating property, the electronic components may be in direct contact with the contact wall portion.

(6) In the above embodiments 1 and 2, the insulating material 40 is described as provided between the circuit board 12 and the contact wall portion 26, 126. However, for example, in a case where the contact wall portion has an insulating property, the insulating material may be omitted.

The disclosure has been described in detail with reference to the above embodiments. However, the disclosure should not be construed as being limited thereto. It should further be apparent to those skilled in the art that various changes in form and detail of the disclosure as shown and described above may be made. It is intended that such changes be included within the spirit and scope of the claims appended hereto.

This application is based on Japanese Patent Application No. 2023-143417 filed Sep. 5, 2023, the disclosure of which is incorporated herein by reference in its entirety.

What is claimed is:

1. A heating device comprising:
a circuit board;
an electronic component provided on the circuit board;
a casing having formed therein a storage space in which the circuit board is stored and a flow path through which a heat medium flows; and
a heater which is provided in the flow path and is configured to heat the heat medium, wherein
a plurality of wall portions forming the storage space include a contact wall portion with which the electronic component directly or indirectly contacts, and
the contact wall portion is configured to be in contact with outside air.

2. The heating device according to claim 1, wherein
the contact wall portion has a largest outside-air contact area among the plurality of wall portions.

3. The heating device according to claim 1, wherein
the casing is formed by having the contact wall portion and a casing body to/from which the contact wall portion being configured to be attachable and detachable.

4. The heating device according to claim 1, wherein
the contact wall portion has a plurality of fins configured for contact with the outside air.

5. The heating device according to claim 1, wherein
the contact wall portion is formed of a heat dissipation plate made of metal.

6. The heating device according to claim 1, wherein
the electronic component is in contact with a central-side part of the contact wall portion.

7. The heating device according to claim 2, wherein
the casing is formed by having the contact wall portion and a casing body to/from which the contact wall portion being configured to be attachable and detachable.

8. The heating device according to claim 2, wherein
the contact wall portion has a plurality of fins configured for contact with the outside air.

9. The heating device according to claim 2, wherein
the contact wall portion is formed of a heat dissipation plate made of metal.

10. The heating device according to claim 2, wherein
the electronic component is in contact with a central-side part of the contact wall portion.

11. The heating device according to claim 1, wherein
the electronic component is configured to generate heat when in use.

12. The heating device according to claim 2, wherein
the electronic component is configured to generate heat when in use.
